(19) United States
(12) Patent Application Publication
(10) Pub. No.: US 2011/0233537 A1
(43) Pub. Date: Sep. 29, 2011

(54) OXIDE THIN FILM TRANSISTOR AND METHOD FOR MANUFACTURING THE SAME

(75) Inventors: Fang-An SHU, Hsinchu City (TW); Ted-Hong Shinn, Hsinchu City (TW); Sung-Hui Huang, Hsinchu City (TW); Lee-Ting Chen, Hsinchu City (TW); Yung-Sheng Chang, Hsinchu City (TW)

(73) Assignee: E Ink Holdings Inc., Hsinchu (TW)

(21) Appl. No.: 12/840,362

(22) Filed: Jul. 21, 2010

(30) Foreign Application Priority Data
Mar. 26, 2010 (TW) 099109135

(51) Int. Cl. H01L 29/786; H01L 21/34

(52) U.S. Cl. 257/43; 438/104; 438/158; 257/E29.296; 257/E21.46

(57) ABSTRACT

An oxide thin film transistor includes a substrate, a gate layer, an oxide film and a gate insulating layer. The gate layer is disposed on the substrate. The oxide film is disposed on the substrate, and has a source region, a drain region and a channel region. The channel region is located between the source region and the drain region and corresponds to the gate layer. The electric conductivity of the source region and the drain region is greater than that of the channel region. The gate insulating layer is disposed on the substrate and located between the gate layer and the oxide film.

### CROSS-REFERENCE TO RELATED APPLICATION

This application claims the priority benefit of Taiwan application serial No. 099109135, filed on Mar. 26, 2010. The entirety of the above-mentioned patent application is incorporated herein by reference and made a part of this specification.

### BACKGROUND

1. Technical Field

The present invention relates to a thin film transistor, and more particularly to an oxide thin film transistor and a method for manufacturing the oxide thin film transistor.

2. Description of the Related Art

Thin film transistors are used widely in various electronic products with display devices. For example, the electronic products are a mobile phone or a television, and the display devices are a thin film transistor liquid crystal display device (TFT LCD), an electrophoretic display device (EPD) or an organic light emitting diode display device (OLED). Therefore, people have always paid close attention to research and development of the thin film transistor structure and manufacturing process.

Generally, the thin film transistor includes a substrate, a gate, a gate insulating layer, a source, a channel region and a drain. The source, the channel region and the drain are disposed on the gate insulating layer, and the source and the drain are connected with the channel region. In a manufacturing process of the conventional thin film transistor, material of the source and the drain is different from that of the channel region, and this makes the manufacturing process complicated. Furthermore, the material of the source and the drain commonly includes metal or metal compound. Because the metal and the metal compound are commonly opaque, the display device that uses the thin film transistor as a driving element displays images only on a side that is far away from the thin film transistor array, and can not display images on double sides.

### BRIEF SUMMARY

The present invention relates to an oxide thin film transistor, which can be manufactured simply and can be transparent.

The present invention also relates to a method for manufacturing an oxide thin film transistor, which can manufacture a transparent oxide thin film transistor using a simplified manufacturing process.

The present invention provides an oxide thin film transistor. The oxide thin film transistor includes a substrate, a gate layer, an oxide film and a gate insulating layer. The gate layer is disposed on the substrate. The oxide film is disposed on the substrate, and has a source region, a drain region and a channel region. The channel region is located between the source region and the drain region and corresponds to the gate layer. The electric conductivity of the source region and the drain region is greater than that of the channel region. The gate insulating layer is disposed on the substrate and located between the gate layer and the oxide film.

In an embodiment of the present invention, the material of the oxide film is, for example, indium gallium zinc oxide or indium zinc oxide, and the material of the gate layer can be indium tin oxide.

In an embodiment of the present invention, the gate insulating layer covers the gate layer, and the oxide film is disposed on the gate insulating layer.

In an embodiment of the present invention, the gate insulating layer is disposed on the channel region of the oxide film, and the gate layer is disposed on the gate insulating layer.

The present invention also provides a method for manufacturing an oxide thin film transistor, which includes the following steps. First, a substrate is provided. Next, a gate layer, a gate insulating layer and an oxide semiconductor layer are formed on the substrate. The gate insulating layer is located between the gate layer and the oxide semiconductor layer. The oxide semiconductor layer has a predetermined source region, a predetermined drain region and a channel region. The channel region is located between the predetermined source region and the predetermined drain region. Next, a conductive treatment process is applied to the predetermined source region and the predetermined drain region, so as to form an oxide film having the channel region, a source region and a drain region on the gate insulating layer.

In an embodiment of the present invention, a method for forming the gate layer, the gate insulating layer and the oxide semiconductor layer includes the following steps. First, the gate layer and the gate insulating layer are formed on the substrate in above mentioned order so that the gate insulating layer covers the gate layer. Then the oxide semiconductor layer is formed on the gate insulating layer.

In an embodiment of the present invention, a method for forming the gate layer, the gate insulating layer and the oxide semiconductor layer includes the following steps. First, the oxide semiconductor layer is formed on the substrate. Next, the gate insulating layer is formed on the channel region of the oxide semiconductor layer. Next, the gate layer is formed on the gate insulating layer. In addition, the channel region is covered by, for example, a mask or photoresist during the conductive treatment process.

In an embodiment of the present invention, the conductive treatment process includes a plasma treatment process, an ultraviolet irradiation process or a laser irradiation process. Gas used in the plasma treatment process can include argon, ammonia or hydrogen gas.

In the oxide thin film transistor of the present invention, because the source region, the drain region and the channel region are formed in the same oxide semiconductor layer, it is unnecessary that an additional metal layer or metal compound layer is deposited to form a source region and a drain region, and the manufacturing process can be simplified. In addition, because the substrate, the gate layer and the gate insulating layer can be made of the transparent material, the oxide thin film transistor can be substantially transparent. Accordingly, the oxide thin film transistor array using the oxide thin film transistor can be substantially transparent. And thus the display device using the oxide thin film transistor of the present invention can achieve displaying images on double sides thereof.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic cross-sectional view of an oxide thin film transistor according to the first embodiment of the present invention.

FIG. 2 is a schematic cross-sectional view of an oxide thin film transistor according to the second embodiment of the present invention.

FIG. 3 is a schematic cross-sectional view of a display device according to the third embodiment of the present invention.

FIG. 4 is a flow chart of a method for manufacturing an oxide thin film transistor according to the fourth embodiment of the present invention.

FIGS. 5A-5F are schematic cross-sectional views of portion of the oxide thin film transistor in some steps of FIG. 4.

FIG. 6 is a flow chart of a method for manufacturing an oxide thin film transistor according to the fifth embodiment of the present invention.

FIGS. 7A-7D are schematic cross-sectional views of portion of the oxide thin film transistor in some steps of FIG. 6.

### DETAILED DESCRIPTION

It is to be understood that other embodiment may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings.

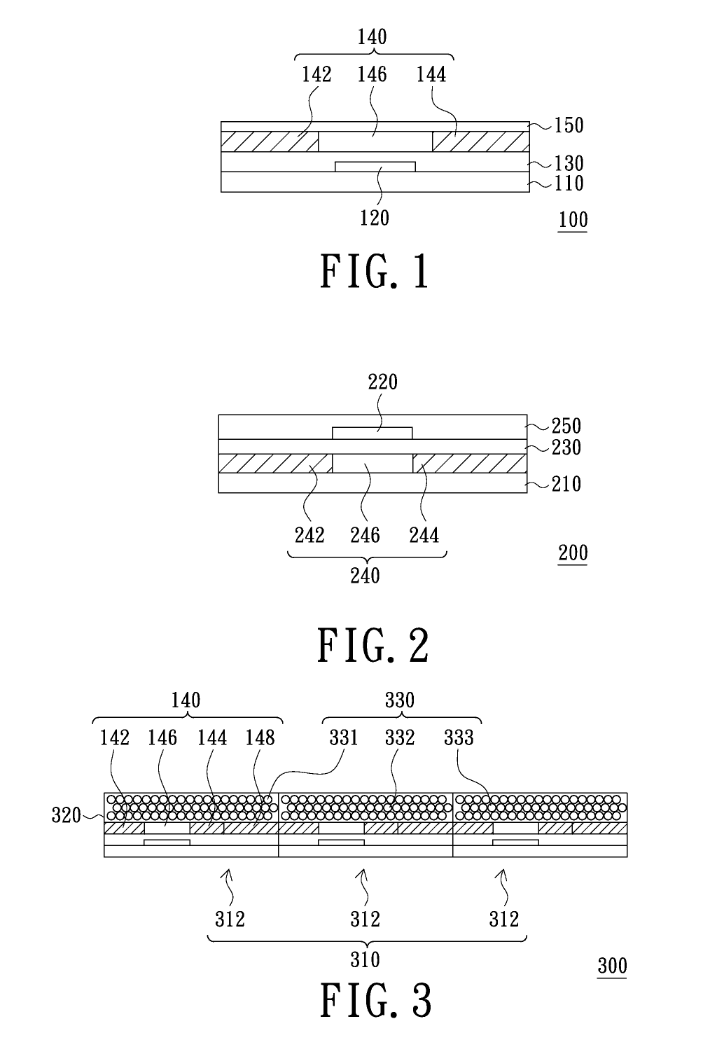

FIG. 1 is a schematic cross-sectional view of an oxide thin film transistor according to the first embodiment of the present invention. Referring to FIG. 1, the oxide thin film transistor 100 includes a substrate 110, a gate layer 120, a gate insulating layer 130 and an oxide film 140.

The substrate 110 can be made of transparent material, such as glass, silicon dioxide or polyimide, but not limited hereto. The substrate 110 is used to support the gate layer 120, the oxide film 140 and the gate insulating layer 130. In the present embodiment, the gate layer 120 is disposed on the substrate 110. In other words, the oxide thin film transistor 100 of the present embodiment is a bottom gate thin film transistor. The gate layer 120 can be made of indium tin oxide (ITO), but not limited hereto. The gate insulating layer 130 covers the substrate 110 and the gate layer 120. The gate insulating layer 130 can be made of silicon dioxide, but not limited hereto. The oxide film 140 is formed on the gate insulating layer 130, that is, the gate insulating layer 130 is located between the gate layer 120 and the oxide film 140.

The oxide film 140 can be made of indium gallium zinc oxide (InGaZnO) or indium zinc oxide (InZnO), but not limited hereto. The oxide film 140 has a source region 142, a drain region 144 and a channel region 146. In other words, the source region 142, the drain region 144 and the channel region 146 are formed in the same oxide film 140. The channel region 146 is located between the source region 142 and the drain region 144. The source region 142 and the drain region 144 are electric conductive, and the channel region 146 is electric semi-conductive. In other words, the electric conductivities of the source region 142 and the drain region 144 are greater than that of the channel region 146.

In addition, a protective layer 150 is formed on a surface of the oxide film 140 to cover and protect the oxide film 140. The protective layer 150 can includes silicon dioxide, but not limited hereto. In an alternative embodiment, the protective layer 150 on the oxide film 140 can be omitted.

In the oxide thin film transistor 100 of the present embodiment, because the oxide film 140 has the source region 142, the drain region 144 and the channel region 146, it is unnecessary that an additional metal layer or metal compound layer is deposited to form a source and a drain of the thin film transistor 100, and the manufacturing process can be simplified. In addition, because the substrate 110, the gate layer 120 and the gate insulating layer 130 can be made of transparent material, the oxide thin film transistor 100 can be substantially transparent. Accordingly, the thin film transistor array using the oxide thin film transistor 100 can be substantially transparent.

The above embodiment takes the bottom gate oxide thin film transistor as an example, but the present invention is not limited hereto. FIG. 2 is a schematic cross-sectional view of an oxide thin film transistor according to the second embodiment of the present invention. Referring to FIG. 2, the oxide thin film transistor 200 of the second embodiment is a top gate oxide thin film transistor. The difference between the oxide thin film transistor 100 of FIG. 1 and the oxide thin film transistor 200 of the present embodiment lies in a relative position of a gate layer 220, a gate insulating layer 230 and an oxide film 240.

In details, the oxide film 240 is formed on a substrate 210, and has a source region 242, a drain region 244 and a channel region 246. The gate insulating layer 230 covers the substrate 210 and the oxide film 240. The gate layer 220 is formed on the gate insulating layer 230 and corresponds to the channel region 246 of the oxide film 240. Material of the gate layer 220, the gate insulating layer 230 and the oxide film 240 can be the same as or similar to that of the gate layer 120, the gate insulating layer 130 and the oxide film 140 of the first embodiment correspondingly.

In addition, a protective layer 250 is formed on the surfaces of the gate layer 220 and the gate insulating layer 230 to cover and protect the gate layer 220 and the gate insulating layer 230. The protective layer 250 includes silicon dioxide, but not limited hereto.

As described above, the oxide thin film transistors of the embodiments of the present invention are disclosed, and a display device with the oxide thin film transistors of the embodiments of the present invention is to be described as follows and is accompanied with figures.

FIG. 3 is a schematic cross-sectional view of a display device according to the third embodiment of the present invention. Referring to FIG. 3, the display device 300 includes an oxide thin film transistor array 310 and a display layer 320. The oxide thin film transistor array 310 includes a plurality of oxide thin film transistors 312. In the embodiment, the oxide thin film transistor 312 is the same as or similar to the oxide thin film transistor 100 of the first embodiment. However, those skilled in the art should know that the present invention is not limited hereto. In other embodiments, the oxide thin film transistor 312 of the display device 300 can be the oxide thin film transistor 200 of the second embodiment or other transparent oxide thin film transistor.

Specially, in the third embodiment, an oxide film 140 of the oxide thin film transistor 312 can further include a pixel electrode region 148 extending from the drain region 144 to be the pixel electrode of the display device 300. In an alternative embodiment, the pixel electrode region 148 can be made of other transparent conductive material but not limited hereto.

The display layer 320 is disposed on the oxide thin film transistor array 310. The display layer 320 can be an electrophoretic display layer or a liquid crystal display layer. In the third embodiment, the electrophoretic display layer is, for example, a microcapsule electrophoretic display layer or a microcup electrophoretic display layer. The display layer 320 can includes a plurality of display units groups 330. Each of the display units groups 330 can include at least one display unit. In the embodiment, each of the display units groups 330 includes three display units 331, 332 and 333, but not limited hereto. The three display units 331, 332 and 333 can respectively include red electrophoretic particles, green electrophoretic particles and blue electrophoretic particles, but not limited hereto. Each of the display units groups 330 belongs to a pixel of the display device 300. Movement of the different color electrophoretic particles in the three display units 331, 332 and 333 can be controlled by the oxide thin film transistor 312 correspondingly, so that the three display units 331, 332 and 333 can display predetermined color as required.

In the third embodiment, the display layer 320 is the electrophoretic display layer and the oxide thin film transistor array 310 is transparent. Therefore, the images not only can be displayed above the display layer 320 but also can be displayed under the oxide thin film transistor array 310. Thus the display device 300 is a double-sided display device.

A method for manufacturing the oxide thin film transistor is to be described as follows and is accompanied with figures.

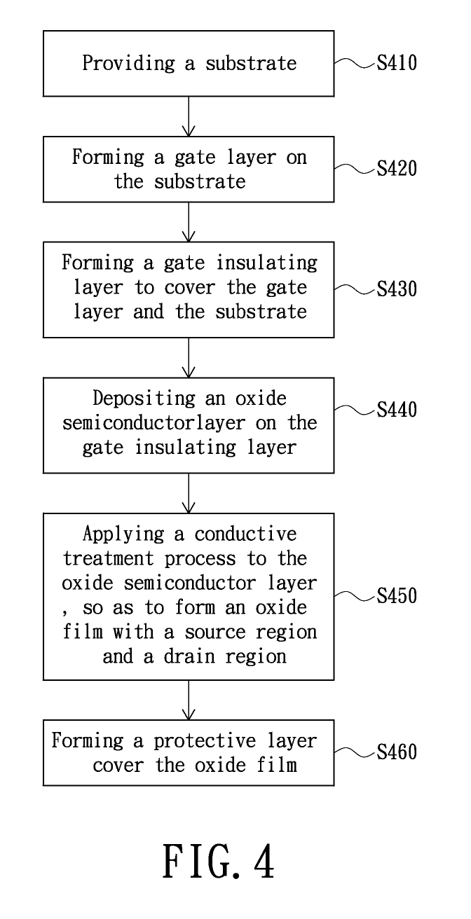

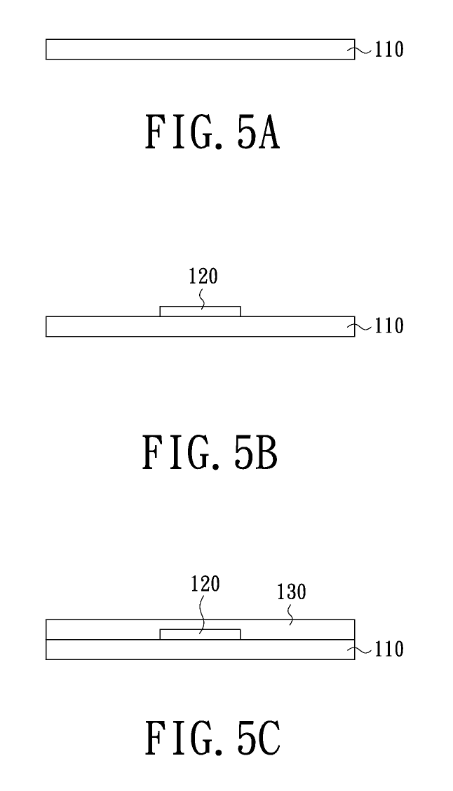

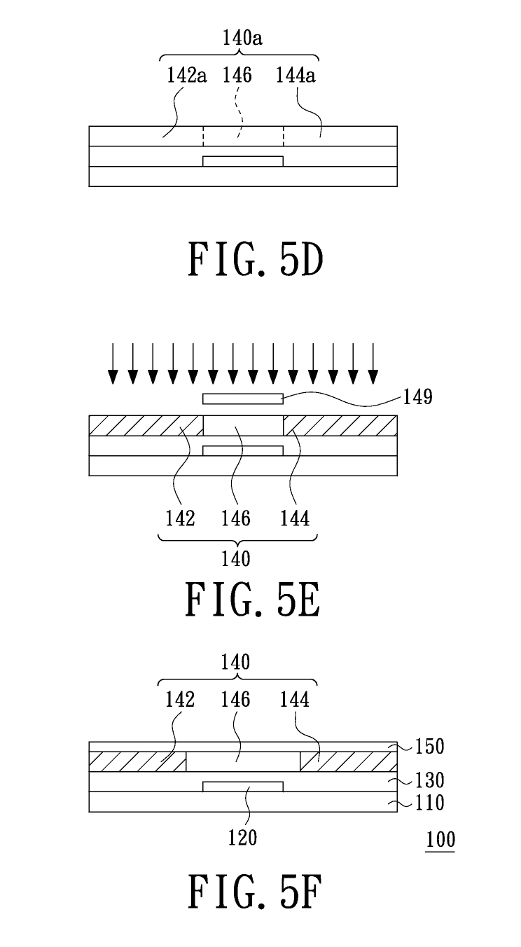

FIG. 4 is a flow chart of a method for manufacturing an oxide thin film transistor according to the fourth embodiment of the present invention. FIGS. 5A-5F are schematic views of portion of the oxide thin film transistor in some steps of FIG. 4.

Referring to FIG. 4 and FIG. 5A, in the step S410, a substrate 110 is provided firstly. The substrate 110 can be made of transparent material, such as glass, silicon dioxide or polyimide, but not limited hereto.

Referring to FIG. 4 and FIG. 5B, in the step S420, a gate layer 120 is formed on the substrate 110. The gate layer 120 can be made of transparent conductive material, such as indium tin oxide (ITO), but not limited hereto. A method of forming the gate layer 120 can include: depositing a transparent conductive material layer on the substrate 110 firstly and then performing a patterning process to form the gate layer 120.

Referring to FIG. 4 and FIG. 5C, in the step S430, a gate insulating layer 130 is formed to cover the gate layer 120 and the substrate 110. The gate insulating layer 130 can be made of silicon dioxide, but not limited hereto. A method of forming the gate insulating layer 130 can include a chemical vapor deposition process, but not limited hereto. The silicon dioxide can be deposited by using organic silicon as a silicon supply source and using oxidant as an oxygen supply source. The organic silicon can be tetraethoxysilane (TEOS) or silane. The oxidant can be oxygen gas, ozone or oxynitride.

Referring to FIG. 4 and FIG. 5D, in the step S440, an oxide semiconductor layer 140a is deposited on the gate insulating layer 130. The oxide semiconductor layer 140a can be made of indium gallium zinc oxide (InGaZnO) or indium zinc oxide (InZnO), but not limited hereto. A method of depositing the oxide semiconductor layer 140a can include a chemical vapor deposition process, but not limited hereto. The oxide semiconductor layer 140a includes a predetermined source region 142a, a predetermined drain region 144a, and a channel region 146. The channel region 146 is located between the predetermined source region 142a and the predetermined drain region 144a.

Referring to FIG. 4 and FIG. 5E, at the step S450, a conductive treatment process is applied to a portion of the oxide semiconductor layer 140a, so as to form a source region 142 and a drain region 144. In details, the conductive treatment process can include a plasma treatment process, an ultraviolet irradiation process or a laser irradiation process. If the conductive treatment process includes the plasma treatment process, gas used in the plasma treatment process can includes argon (Ar), ammonia (NH₃) or hydrogen gas (H₂), but not limited hereto. Referring to FIG. 5E, when the conductive treatment process is applied, the channel region 146 can be shielded by a mask 149. In an alternative embodiment, a patterned photoresist layer can be formed on the oxide semiconductor layer 140a to shield the channel region 146 at first, and after the conductive treatment process is applied, the patterned photoresist layer is removed.

In the conductive treatment process, because the plasma treatment process, the ultraviolet irradiation process or the laser irradiation process can make energy levers of the oxide semiconductor material change, the predetermined source region 142a and the predetermined drain region 144a may be converted from a semiconductor to a conductor. The channel region 146 is shielded by the mask 149, therefore the channel region 146 can keep the original semi-conductivity thereof.

After the conductive treatment process is applied, the predetermined source region 142a and predetermined drain region 144a are converted to the source region 142 and the drain region 144 correspondingly. In other words, after the conductive treatment process is applied, the oxide semiconductor layer 140a is converted to an oxide film 140 with the source region 142, the drain region 144 and the channel region 146.

Referring to FIG. 4 and FIG. 5F, in the step S460, a protective layer 150 is formed to cover the oxide film 140. Material of the protective layer 150 can be silicon dioxide. A method of forming the protective layer 150 can be the same as or similar to that of forming the gate insulating layer 130.

After the above steps are carried out, the oxide thin film transistor 100 is formed in FIG. 1. In the oxide thin film transistor 100, because the oxide film 140 has the source region 142, the drain region 144 and the channel region 146, it is unnecessary that an additional metal layer or metal compound layer is deposited to form a source and a drain of the oxide thin film transistor 110, and the manufacturing process can be simplified. In addition, because the substrate 110, the gate layer 120 and the gate insulating layer 130 can be made of the transparent material, the oxide thin film transistor 100 can be substantially transparent. Accordingly, the oxide thin film transistor array using the oxide thin film transistor 100 can be substantially transparent.

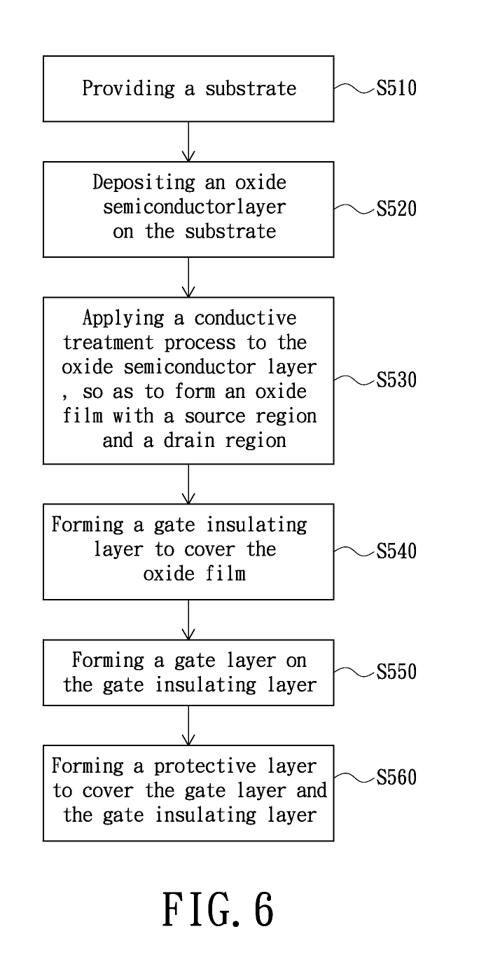

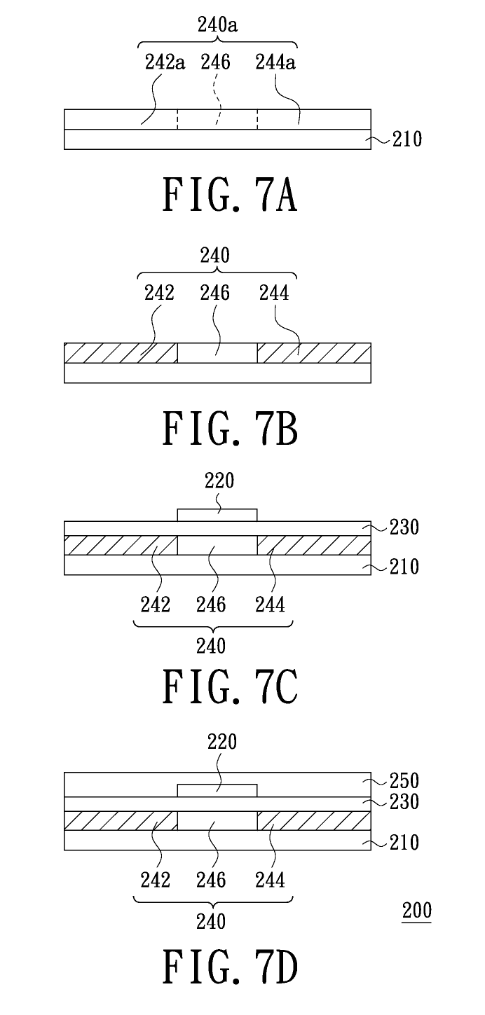

Depending on the method of the above embodiments, the transparent bottom gate oxide thin film transistor can be manufactured. The following would describe a method for manufacturing the top gate oxide thin film transistor 200 shown in FIG. 2. FIG. 6 is a flow chart of a method for manufacturing an oxide thin film transistor 200 according to the fifth embodiment of the present invention. FIGS. 7A-7D are schematic cross-sectional views of portion of the oxide thin film transistor 200 in some steps of FIG. 6.

Referring to FIG. 6 and FIG. 7A, in the steps S510 and S520, a substrate 210 is provided firstly, and an oxide semiconductor layer 240a is deposited on the substrate 210. The oxide semiconductor layer 240a includes a predetermined source region 242a, a predetermined drain region 244a, and a channel region 246. The channel region 246 is located between the predetermined source region 242a and the predetermined drain region 244a. Methods and material of forming the substrate 210 and the oxide semiconductor layer 240a can be the same as or similar to that of the substrate 110 and the oxide semiconductor layer 140a of the above embodiment correspondingly.

Referring to FIG. 6 and FIG. 7B, in the step S530, a conductive treatment process is applied to a portion of the oxide semiconductor layer 240a, so as to form a source region 242 and a drain region 244. A method of the conductive treatment process can be the same as or similar to that of the above embodiment. After the conductive treatment process is applied, the predetermined source region 242a and predetermined drain region 244a are converted to the source region 242 and the drain region 244 correspondingly. In other words, after the conductive treatment process is applied, the oxide semiconductor layer 240a is converted to an oxide film 240 with the source region 242, the drain region 244 and the channel region 246.

Referring to FIG. 6 and FIG. 7C, in the steps S540 and S550, a gate insulating layer 230 is formed to cover the oxide film 240, and then a gate layer 220 is formed on the gate insulating layer 230. Methods and material of forming the gate layer 220 and the gate insulating layer 230 can be the same as or similar to that of the gate layer 120 and the gate insulating layer 130 of the above embodiment correspondingly.

Referring to FIG. 6 and FIG. 7D, in the step S560, a protective layer 250 is formed to cover the gate layer 220 and the gate insulating layer 230. A method and material of forming protective layer 250 can be the same as or similar to that of the protective layer 150 of the above embodiment.

After the above steps are carried out, the oxide thin film transistor 200 of the second embodiment is formed. In addition, in other embodiment, after the oxide semiconductor layer 240a is formed, the gate insulating layer 230 and the gate layer 220 can be formed orderly, and then the conductive treatment process is applied by using the gate layer 220 as a mask. In other words, when the top gate oxide thin film transistor is manufactured by the method of the present invention, using an additional mask can be omitted during the conductive treatment process. Consequently, the manufacturing process is further simplified.

Referring to FIG. 3 again, a method for manufacturing a display device 300 can includes: forming an oxide thin film transistor array 310 firstly, and then forming a display layer 320 on the oxide thin film transistor array 310. The oxide thin film transistor array 310 can includes a plurality of oxide thin film transistors 312. Each of the oxide thin film transistors 312 can be manufacturing by methods that are the same as or similar to the methods for manufacturing the oxide thin film transistors 100 and 200.

It should be noted that, the oxide thin film transistor array 310 can also include a plurality of scan lines and data lines (not shown). It is well known to the people skilled in the art that the scan lines and the gate layer 110 can be made in the same process, and the data lines and the oxide film 140 can be made in the same process. In details, referring to FIG. 5C, the data lines and the oxide semiconductor layer 140a can be the same layer. When the conductive treatment process is applied to the predetermined source region 142a and predetermined drain region 144a, a region for forming the data lines can also be treated to convert to the data lines.

In addition, in the embodiment, the oxide film 140 can further include a pixel electrode region 148 extending from the drain region 144 to be the pixel electrode of the display device 300. In an alternative embodiment, the pixel electrode (not shown) of the display device 300 can be made by using different process from the process of the oxide film 140. That is, the pixel electrode of the display device 300 and the oxide film 140 can be formed separately, and then the pixel electrode is electrically connected with the drain region 144 of the oxide film 140.

As described above, in the method for manufacturing the display device of the embodiment, because the oxide film has the source region, the drain region and the channel region, it is unnecessary that an additional conductive layer is deposited to form a source and a drain of the oxide thin film transistor, and the manufacturing process can be simplified. In addition, because all layers of the oxide thin film transistor can be made of the transparent material, the oxide thin film transistor, the oxide thin film transistor array and the display device using the oxide thin film transistor array can all be substantially transparent, and thus the display device can achieve displaying images on double sides thereof.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. An oxide thin film transistor comprising:
a substrate;
a gate layer disposed on the substrate;
an oxide film disposed on the substrate, and having a source region, a drain region and a channel region, the channel region located between the source region and the drain region and corresponding to the gate layer, the electric conductivity of the source region and the drain region being greater than that of the channel region; and
a gate insulating layer disposed on the substrate, and located between the gate layer and the oxide film.

2. The oxide thin film transistor as claimed in claim 1, wherein the oxide film comprises indium gallium zinc oxide or indium zinc oxide.

3. The oxide thin film transistor as claimed in claim 1, wherein material of the gate layer comprises indium tin oxide.

4. The oxide thin film transistor as claimed in claim 1, wherein the gate insulating layer covers the gate layer, and the oxide film is disposed on the gate insulating layer.

5. The oxide thin film transistor as claimed in claim 1, wherein the gate insulating layer is disposed on the channel region of the oxide film, and the gate layer is disposed on the gate insulating layer.

6. A method for manufacturing an oxide thin film transistor, comprising:
providing a substrate;
forming a gate layer, a gate insulating layer and an oxide semiconductor layer, the gate insulating layer located between the gate layer and the oxide semiconductor layer, the oxide semiconductor layer having a predetermined source region, a predetermined drain region and a channel region, the channel region located between the predetermined source region and the predetermined drain region; and
applying a conductive treatment process to the predetermined source region and the predetermined drain region, so as to form an oxide film having the channel region, a source region and a drain region on the gate insulating layer.

7. The method for manufacturing an oxide thin film transistor as claimed in claim 6, wherein a method for forming the gate layer, the gate insulating layer and the oxide semiconductor layer comprises:
forming the gate layer and the gate insulating layer on the substrate in above mentioned order so that the gate insulating layer covers the gate layer; and
forming the oxide semiconductor layer on the gate insulating layer.

8. The method for manufacturing an oxide thin film transistor as claimed in claim 6, wherein a method for forming the gate layer, the gate insulating layer and an oxide semiconductor layer comprises:
forming the oxide semiconductor layer on the substrate;
forming the gate insulating layer on the channel region of the oxide semiconductor layer; and
forming the gate layer on the gate insulating layer.

9. The method for manufacturing an oxide thin film transistor as claimed in claim 6, wherein the conductive treatment process comprises a plasma treatment process, and gas used in the plasma treatment process comprises argon, ammonia or hydrogen gas.

10. The method for manufacturing an oxide thin film transistor as claimed in claim 6, wherein the conductive treatment process comprises an ultraviolet irradiation process or a laser irradiation process.
